(19) United States
(12) Patent Application Publication
(10) Pub. No.: US 2009/0269702 A1
(43) Pub. Date: Oct. 29, 2009

(54) METHOD FOR INTRODUCING INCLUSION IMAGE INTO GEMSTONE

(75) Inventors: Arthur C. GARABEDIAN, Anaheim, CA (US); Marcus GARABEDIAN, Mission Viejo, CA (US)

Correspondence Address: THE MAXHAM FIRM, 9330 SCRANTON ROAD, SUITE 350, SAN DIEGO, CA, 92121, US

(73) Assignee: DIRECT SHOPPING NETWORK, LLC, Glendale, CA (US)

(21) Appl. No.: 12/111,932

(22) Filed: Apr. 29, 2008

(51) Int. Cl. G03F 7/00

(52) U.S. Cl. 430/290

(57) ABSTRACT

A gemstone having an image formed by a manufactured color inclusion and method for making same. The gemstone is of a type that is heat sensitive and undergoes a color phase transformation upon heat treatment. The image is formed by tracing a focused laser beam along a linear trail within the interior of the gemstone so as to heat the linear trail for precipitating the color phase transformation and creating the color inclusion. The image is formed by the newly formed color inclusion.

### FIELD OF INVENTION

The invention relates generally to gemstones containing an image and to methods for manufacturing such gemstones.

### BACKGROUND

Gemstones that undergo a permanent color phase transformation upon heating have been known since the Middle Ages. Cistercian monks are reported to have heat treated fossilized mastodon ivory during the medieval period to create odontolite, aturquoise-blue gemstone, for use in making decorative art objects. The color phase transformation that appears when heat treating fossilized mastodon ivory to make odontolite has been shown to correspond to fluorapatite [Ca₅(PO₄)₃F] containing trace amounts of Fe (230-890 ppm), Mn (220-650 ppm), Ba (160-620 ppm), Pb (40-140 ppm), and U (80-210 ppm) (Ina Reiche, et al., American Mineralogist (November 2001) v. 86; no. 11-12; p. 1519-1524. During heat treatment, the gemstone is heated to very high temperatures (approximately 1600° Centigrade) causing inclusions, chemical elements, and other impurities to reform themselves and change the color of the stone. Collectively, these temperature induced color changes are known a color phase transitions. These color changes may result either in the stone being darker, lighter, more intense, or of a different color. A partial list of other heat sensitive gemstones that are known to undergo a color phase transformation upon heat treatment includes the following: andesine, amethyst, citrine, ametrine, aquamarine, tourmaline, topaz, light green tourmaline, sapphire, ruby, tanzanite, and blue zircon.

Heat treatment can also be employed to chemically alter gemstones so as to create microscopic inclusions. U.S. Pat. No. 7,284,396 discloses a method for forming microscopic dot patterns embedded within the interior of diamonds. The microdot patterns serve as identification marks for the diamonds and are visible only by the use of magnification. The microdots are opaque inclusions formed by conversion of diamond to an opaque form of carbon created by an application of intense but focused heat using a focused laser beam of pulsed light. The microdot patterns formed by the process of the '396 patent are not visible to the unaided eye and are not created by a color phase transition, but, rather, are created by a conversion of diamond to graphite or a graphite like substance.

U.S. Pat. Nos. 5,753,887 and 5,760,367 and US patent application 2001/0012055 disclose methods for engraving images onto the surface or into the surface of gemstones. These images may be for identification purposes or for aesthetic purposes. Both the '887 and '367 patents and the '055 patent application disclose apparatuses for effecting these engravings. These apparatuses are computer based and employ a laser beam guided by a scanner and focused by a lens for directing the laser beam onto the surface or subsurface of the gemstone for creating an engraved image. The image is formed when the impinging focused laser beam vaporizes a groove within the surface of the gemstone to form the engraved image. Alternatively, the impinging focused laser beam may cause micro-chipping on or at the surface of the gemstone to form the desired image. These images are on or slightly below a surface of the gem and are gemmologically characterized as “blemishes.” A gemstone is considered “blemished” if it includes surface scratches or marks on the external area of the stone.

### SUMMARY

The invention is directed generally to a method for transferring a visible image to a gemstone without introducing a manufactured blemish, and includes a process for creating an image in a gemstone by introducing a color inclusion, in the shape of the desired image, into the interior of the gemstone. A color inclusion is an inclusion that is differentiated from the remainder of the gemstone by its color. In a preferred embodiment, the color inclusion is large enough to be visible to the unaided eye. However, color inclusion may also be so small that it requires magnification to be viewed. The gemstone is of a type that is transparent or semi-transparent and that is heat sensitive so as to undergo a color phase transition upon being subjected to heat treatment. The color inclusion is created by a heat treatment process and the resultant is a color phase transformation.

The inclusion image is formed by focusing a laser beam on the interior of the gemstone and moving the laser beam along a path within the gemstone so as to leave an color inclusion trail therein. The color inclusion trail is formed by the color phase transformation caused by the heat of the focused laser beam. The process is performed without introducing a blemish on the surface of the gemstone. The invention is also directed generally to gemstones having an inclusion image made by the process of the invention.

### BRIEF DESCRIPTION OF DRAWING

The objects, advantages, and features of the invention, as shown in the exemplary embodiments, will be more clearly perceived from the following description, when read in conjunction with the accompanying drawing, in which:

FIG. 1 is a planar view illustrating a gemstone without an inclusion image;

FIG. 2 is a planar view illustrating the gemstone of FIG. 1 with an inclusion image of The Olympic trademark as covered by the Olympic Trademark Treaty, formed in accordance with the present invention;

FIG. 3 is an enlarged planar view of the table of the gemstone of FIG. 2 illustrating the inclusion image in greater detail;

FIG. 4 is a sectional view of the gemstone taken along cutting plane 4-4 of FIG. 2 illustrating a sectional view of the inclusion image; and

FIG. 5 is a schematic block diagram illustrating a process for forming an inclusion image in accordance with the invention.

### DETAILED DESCRIPTION OF PREFERRED EMBODIMENTS

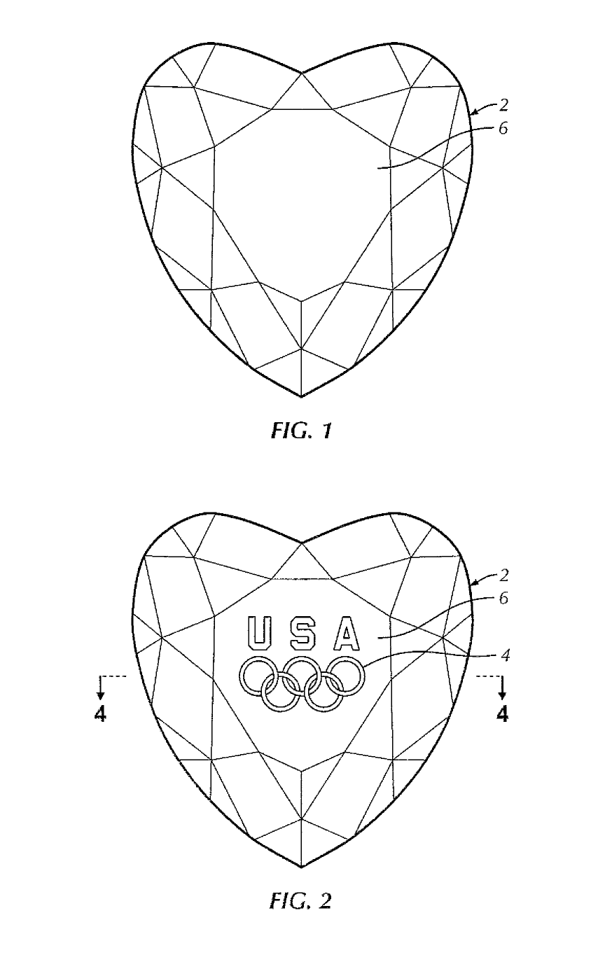

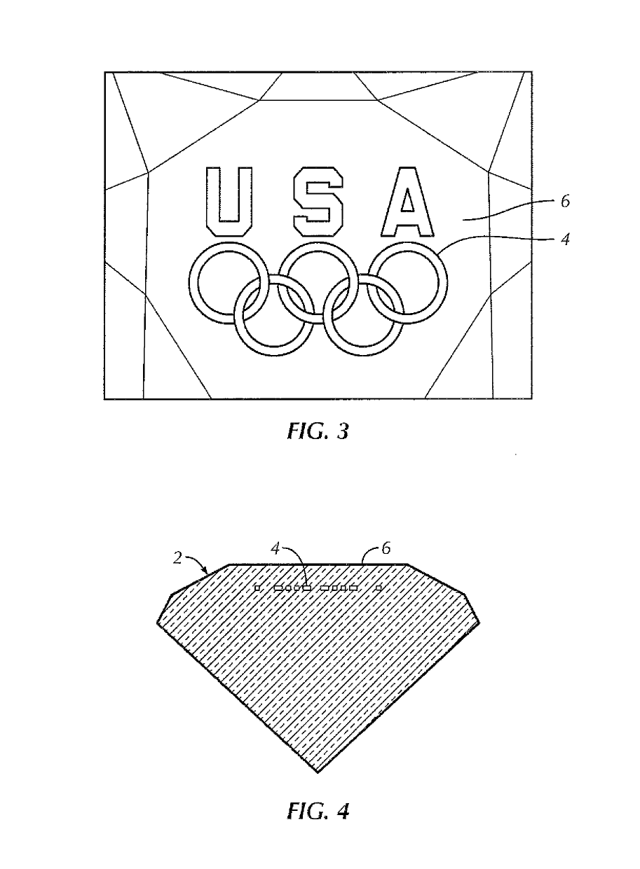

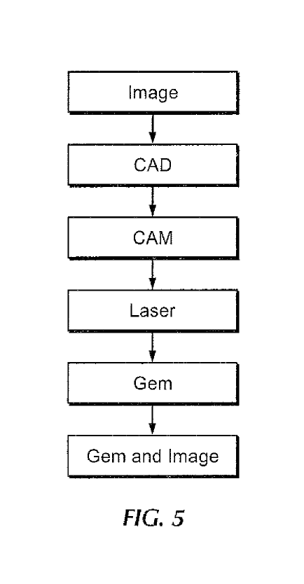

With reference now to the drawing, and more particularly to FIGS. 1-4, one aspect of the invention is directed to a gemstone 2 containing a manufactured color inclusion image 4. In a preferred embodiment of this aspect of the invention, the gemstone is heat sensitive and is capable of undergoing a color phase transition upon heat treatment. In another preferred embodiment, the manufactured color inclusion image 4 is characterized by a linear trail having a total length as long as 50 millimeters or even longer. Within this preferred embodiment, it is preferred that the linear trail does not overlap or cross itself In the preferred embodiment, the linear trail typically includes more than one non-overlapping segment. In the embodiment shown, gemstone 2 includes table 6 and the manufactured color inclusion image 4 is located in a plane beneath the table. In the preferred embodiment, the manufactured color inclusion image 4 is of a type that is manufactured without creating a manufactured blemish.

Another aspect of the invention is directed to a process for manufacturing a gemstone 2 having a desired color inclusion image 4. The process comprises multiple steps. A gemstone 2 is selected that is capable of undergoing a color phase transformation upon heat treatment. The gemstone includes a facet. The selected gemstone is mounted onto an apparatus for treating the facet of the gemstone with a focused laser beam. The focused laser beam is focused within a focus plane beneath the facet. The focused laser beam is moved along a linear trail within the focus plane. The linear trail corresponds to the desired color inclusion image 4. The focused laser beam is moved along the linear trail at a rate sufficient for generating heat for causing the color phase transformation along the linear trail. The desired color inclusion image 4 is created within the gemstone 2 by the color phase transformation along the linear trail. In a preferred mode of this aspect of the invention, the rate at which focused laser beam is moved along its linear trail is sufficient to avoiding causing a blemish. In a preferred mode, the linear trail has a total length of about 50 millimeters or greater. It is preferred that, the linear trail does not cross or overlap itself. Typically, the linear trail includes more than one non-overlapping segment.

The purpose of the process of the invention is to internally mark a gemstone 2 by the introduction of a color inclusion without damaging the interior (except for the introduction of the color inclusion) or the exterior of the gemstone. The mark may be a logo or a trademark. During the process of the invention, a laser beam is directed through table 6 of gemstone 2 to form a high precision focused laser energy spot. This high precision focused laser energy spot follows a predetermined laser beam path to form the image 4. The high precision focused laser energy spot heats the gemstone 2 along the predetermined laser beam path so as to cause a color phase transition. The color phase transition changes the color of the heated portions of the gemstone 2 and forms the color inclusion image 4. The color inclusion image conforms with the shape of the predetermined laser beam path. In a preferred mode, the laser beam path is created using a software program for computer aided design (CAD) and the laser is a near-field optical imaging laser. During laser processing, the gemstone is set in a recessed support made of non-reflective material. The support is constructed to engage the facets of the gemstone that are not being treated and to prevent or diminish reflection of laser light from such facets so as to prevent stray heat damage to the gemstone.

### EXAMPLE

An exemplary apparatus for processing gemstone was constructed according to the diagram illustrated in FIG. 5. A commercially available YAG dicode pump laser system of the type sold by Quantronix, Inc., and others, was employed to generate the laser beam. The laser beam emanating from the YAG laser was focused using a conventional four inch F-Theta lens. The F-theta lens is a family of lenses commonly used in scan systems for reading or printing documents. The lens are designed such that the image 4 height is proportional to the scan angle (Theta), not the tangent of that angle, as is usually the case. The precision of the focusing was enhanced using an eight times beam expander. Scanning by the laser beam was achieved by using a conventional two axis galvanometric scan-head. The YAG laser and the scan-head were connected to a computer and controlled thereby. The gemstones were supported by being mounted in a readily available non-reflective cradle. After a gemstone has been properly mounted into its cradle, the cradle is positioned so that the laser beam impinges perpendicularly onto the desired facet of the gemstone. The cradle includes adjustments for adjusting the precise starting position of the gemstone within the laser beam. A low-power infrared alignment beam is employed for precisely aligning the gemstone to its desired starting position within the laser beam. This alignment step is well known. After the gemstone is properly positioned, the laser is activated and the computer drives the scanner to direct the laser beam along its desired path. While it is preferred that the gemstone be fixed and the laser beam moves to create the image, it is possible that the laser can be fixed and the gemstone moved to create the image. A YAG laser is herein identified as being suitable for creating the desired gemstone images, but other lasers may be suitable.

In one example, an eight millimeter round shaped red andesine is placed into the non-reflective cradle. The gemstone 2 is then positioned with its table 6 perpendicular to the laser beam, using the low-power infrared alignment beam to determine the starting position based on the beginning of the DXF (Drawing Exchange Format) file. In this example, the starting position is 1 millimeter above the center of the gemstone 2 and 1.5 millimeters left of center. The laser beam has been pre-focused with another test andesine; the focus depth is 2 millimeters below the surface of the table 6 of the gemstone. Simultaneous with the start of the laser beam the laser beam begins moving along the predetermined path. The predetermined path defines a linear trail consisting of a collection of one or more lines. The lines are non-overlapping and are traced sequentially. The laser is turned off when the focused laser beam moves from one line to the next. In a preferred mode, the path of the “linear trail” and its speed are specified in an Auto-CAD program using DXF “Auto-CAD” is a registered trademark of Autodesk, Inc. In this example, the beam was moved at a rate of about 218 mm per second and the power of the laser is eight watts at a wavelength of 532 nm. The heat of the focused laser beam leaves a color change in the gemstone at the focal point as it follows the path. In the example shown, the powered laser beam travels about 718 mm in 3.29 seconds and produces an image of the US Olympic Rings Logo two millimeters below the surface and parallel to table 6 of gemstone 2, as illustrated in FIGS. 1-4. The Auto-CAD and any other program controls are well within the skill of a programmer once the desired image is defined.

In the above example, the rate at which the laser beam progressed along the linear trail was about 218 mm per second and the power of the laser was chosen at eight watts at a 532 nm wavelength. If the scan rate were increased or the power of the laser decreased, the intensity of the line would diminish. If the scan rate were decreased or the power of the laser increased, the intensity of the line would increase, but there would also be an increased risk of damaging the gemstone. The process for determining the optimal rate for progressing the laser beam along the linear path is dependent upon the desired aesthetics of the image and are particular to each gemstone type and to different batches of gemstones having different color characteristics.

### DEFINITIONS

### Gemstone

A gemstone is any precious or semi-precious gemstone, whether naturally occurring or man-made. The gemstone is conventionally cut and includes several facets, including a table facet. The table facet is the largest of all of the facets.

### Heat Sensitive Gemstone

A heat sensitive gemstone is a gemstone that undergoes a color phase transition upon heat treatment. The gemstone has a first color prior to heat treatment and a second color after heat treatment.

### Color Inclusion Image

An inclusion is an internal characteristic of a gemstone. A color inclusion is an inclusion that is differentiated by color from the remainder of the gemstone. Inclusions may be visible or not to the unaided eye. In a preferred embodiment of the invention, the term “inclusion” is employed herein to mean an internal characteristic apparent to the unaided eye. A color inclusion image is an image within a gemstone formed by a color inclusion.

### Linear Trail

As employed herein, the term “linear trail” is defined to mean the path traced within a focus plane below a facet of a gemstone by the focus point of a focused laser beam. The focus plane is parallel to the surface of the gemstone facet and at least 0.1 millimeter below the surface of the facet. The linear trail consists of a collection of one or more lines. The lines are non-overlapping and are traced sequentially. The laser is turned off when the focused laser beam moves from one line to the next. In a preferred mode, the path of the “linear trail” and its speed are specified is an Auto-CAD program using DXF (Drawing Exchange Format).

### Manufactured Blemish

A blemish is any imperfection on the surface of a gemstone. Examples of blemishes include surface nicks, knots, scratches, abrasions, minor cracks, fissures cavities, poor polish, and surface irregularities. A manufactured blemish is a blemish that results from a manufacturing process.

What is claimed is:

1. A gemstone containing a manufactured color inclusion image.

2. The gemstone according to claim 1, wherein the gemstone is heat sensitive.

3. The gemstone according to claim 1, wherein the manufactured color inclusion image is characterized by a linear trail having a total length of about 50 millimeters or greater.

4. The gemstone according to claim 3, wherein the linear trail does not overlap itself.

5. The gemstone according to claim 4, wherein the linear trail includes more than one non-overlapping segment.

6. The gemstone according to claim 1, wherein the gemstone includes a table and the manufactured color inclusion image is located in a plane beneath the table.

7. The gemstone according to claim 1, wherein the manufactured color inclusion image is of a type that is manufactured without creating a manufactured blemish.

8. A process for manufacturing a gemstone having a desired color inclusion image, the process comprising the steps of:
Step A: selecting a gemstone that is capable of undergoing a color phase transformation upon heat treatment, the gemstone including a facet;
Step B: mounting the gemstone of said Step A onto an apparatus to hold the gemstone for treating the facet of the gemstone with a focused laser beam;
Step C: focusing the focused laser beam within a focus plane beneath the facet; and
Step D: moving the focused laser beam along a linear trail within the focus plane, the linear trail corresponding to the desired color inclusion image, the focused laser beam being moved along the linear trail at a rate sufficient for generating heat for causing the color phase transformation along the linear trail;
whereby the desired color inclusion image is created within the gemstone by the color phase transformation along the linear trail.

9. The process for according to claim 8, wherein in said Step D, the rate at which the focused laser beam is moved along the linear trail is sufficient to avoiding causing a blemish.

10. The process for according to claim 8, wherein in said Step D, the linear trail has a total length of about 50 millimeters or greater.

11. The process for according to claim 8, wherein in said Step D, the linear trail does not overlap itself.

12. The process for according to claim 11, wherein in said Step D, the linear trail includes more than one non-overlapping segment.
